(19) United States
(12) Patent Application Publication
(10) Pub. No.: US 2026/0013038 A1
(43) Pub. Date: Jan. 8, 2026

(54) WIRING SUBSTRATE AND WIRING MEMBER

(71) Applicant: Shanghai AVIC Optoelectronics Co., Ltd., Shanghai (CN)

(72) Inventor: Akira FUJITA, Kawasaki (JP)

(73) Assignee: Shanghai AVIC Optoelectronics Co., Ltd., Shanghai (CN)

(21) Appl. No.: 19/256,691

(22) Filed: Jul. 1, 2025

(30) Foreign Application Priority Data
Jul. 2, 2024 (JP) 2024-106975

(51) Int. Cl. H05K 1/02; H05K 3/28

(52) U.S. Cl. CPC H05K 1/0296; H05K 3/28

(57) ABSTRACT

A wiring layer includes a connection wiring area between a wiring area and a pad. The connection wiring area includes a plurality of connection wiring sections. The plurality of connection wiring sections are individually separated by a plurality of holes. The wiring area includes the plurality of holes that are formed such that a conductive area including the plurality of connection wiring sections has a network structure in the connection wiring area. At least one connection wiring section and at least one hole are allowed to be located in a linear band connecting a connection area located on the wiring area side and a connection area located on the pad side.

### CROSS-REFERENCE TO RELATED APPLICATIONS

This application claims the benefit of Japanese Patent Application No. 2024-106975, filed on Jul. 2, 2024, the entire disclosure of which is incorporated by reference herein.

### FIELD OF THE INVENTION

The present disclosure relates to a wiring substrate and a wiring member.

### BACKGROUND OF THE INVENTION

Wiring substrates are used to mount semiconductors. Examples of the wiring substrates include semiconductor package substrates and printed circuit boards. A method for manufacturing each of such substrates includes forming a wiring circuit pattern and then providing a solder resist for electrically insulating and protecting the wiring circuit pattern, as well as forming a land for mounting a semiconductor. The land is also referred to as a pad.

Lands are known that have a solder mask defined (SMD) structure. Technology is proposed for preventing, in wiring substrates, peeling-off of an insulating layer and a wiring layer caused by aging degradation. In an exemplary redistribution layer disclosed in Japanese Patent Application Publication No. 2011-34988, an outer peripheral area is formed around a land. In this structure, a sealing insulating layer and an interlayer insulating layer are joined at a gap between the land and the outer peripheral area.

A method for manufacturing a land having a SMD structure includes forming a solder resist layer as an insulating layer on the land and then forming an opening in the solder resist layer, as well as exposing a part of the land in copper wiring. A surface of the land exposed through the opening is treated by etching, and protective plating treatment is then performed on the land. For example, the protective plating treatment is performed with electroless nickel immersion gold (ENIG). Peeling-off of a wiring layer and an insulating layer may be caused by treatment of such protective plating or the like to be formed on the land, not only by aging degradation.

Specifically, as illustrated in a cross-sectional view PA01 and a plan view PB01 in FIG. 13, an opening 703A is formed in an insulating layer 703, and a part of a wiring layer 702 with copper wiring is exposed. Next, etching performed as pretreatment for protective plating treatment causes stresses such as undercuts 711 in the wiring layer 702 with copper wiring and immersion of various chemical solutions in a joint 712A, as illustrated in a cross-sectional view PA02 and a plan view PB02 in FIG. 13. This causes peeling-off of the insulating layer and the wiring layer and, as a result, causes penetration of the various chemical solutions into the peeled-off area and contamination. This results in a problem in that a surface of the copper wiring is transformed. In worse cases, damage due to peeling-off of the insulating layer, corrosion or wire break of the copper wiring, and the like may be caused. As illustrated in a cross-sectional view PA03 and a plan view PB03 in FIG. 13, even after a Ni layer 721 and an Au layer 722 are formed by the protective plating treatment, peeling-off and surface transformation in the joint 712B may expand.

### SUMMARY OF THE INVENTION

A wiring substrate according to a first aspect of the present disclosure includes:

a support substrate;

a wiring layer formed on the support substrate and including main wiring and an electrical contact;

an insulating layer having an opening corresponding to at least a part of the electrical contact, the insulating layer covering the wiring layer; and

a protective plating layer formed on a surface of the electrical contact at the opening, wherein

the wiring layer includes a connection area between the main wiring and the electrical contact,

the connection area includes
a plurality of first connection areas located on a side of the main wiring, and
a plurality of second connection areas located on a side of the electrical contact, and

at least one conductive area and at least one non-conductive area are allowed to be located in a linear band connecting one of the plurality of first connection areas and one of the plurality of second connection areas.

A wiring member according to a second aspect of the present disclosure includes:

main wiring;

an electrical contact; and

a connection area provided between the main wiring and the electrical contact, wherein

the connection area includes
a plurality of first connection areas located on a side of the main wiring, and
a plurality of second connection areas located on a side of the electrical contact, and

at least one conductive area and at least one non-conductive area are allowed to be located in a linear band connecting one of the plurality of first connection areas and one of the plurality of second connection areas.

It is to be understood that both the foregoing general description and the following detailed description are exemplary and explanatory and are not restrictive of this disclosure.

### BRIEF DESCRIPTION OF DRAWINGS

FIG. 1 is a plan view illustrating an exemplary configuration of a main part of a wiring substrate according to Embodiment 1;

FIG. 2 is a cross-sectional view taken along line A1-A1 illustrated in FIG. 1;

FIG. 3A is a plan view of a comparative example of a wiring layer with a less wiring width;

FIG. 3B is a cross-sectional view taken along line B1-B1 illustrated in FIG. 3A;

FIG. 4A is a plan view of another comparative example of a wiring layer with a greater wiring width;

FIG. 4B is a cross-sectional view taken along line B2-B2 illustrated in FIG. 4A;

FIG. 5 is an enlarged plan view of a connection wiring area;

FIG. 6 is an enlarged plan view of a connection wiring area from another point of view;

FIG. 7 illustrates an exemplary configuration of a wiring area including a land at an edge thereof;

FIG. 8 is a plan view illustrating a wiring substrate according to Embodiment 2;

FIG. 9 is a plan view illustrating a wiring substrate according to Embodiment 3;

FIG. 10 is a plan view illustrating a wiring substrate according to Embodiment 4;

FIG. 11 is a plan view illustrating a wiring substrate according to Embodiment 5;

FIG. 12 is a plan view illustrating a wiring substrate according to Embodiment 6; and

FIG. 13 includes cross-sectional views and plan views of a related art.

### DETAILED DESCRIPTION OF THE INVENTION

### Embodiment 1

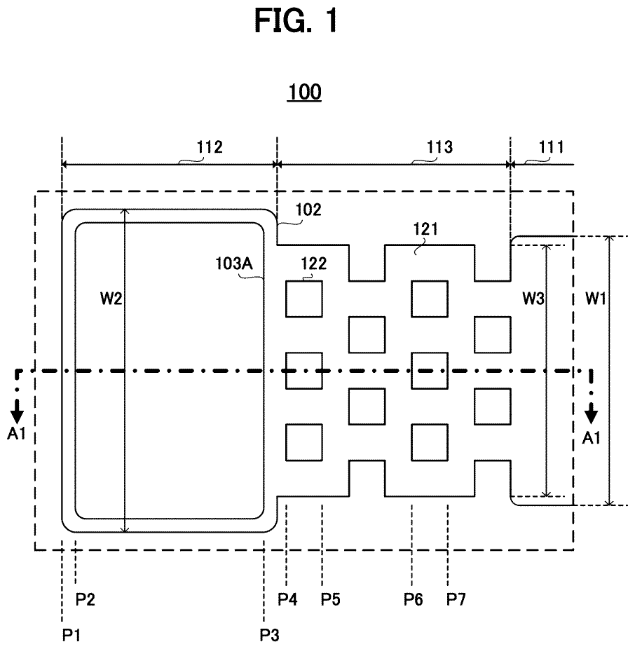

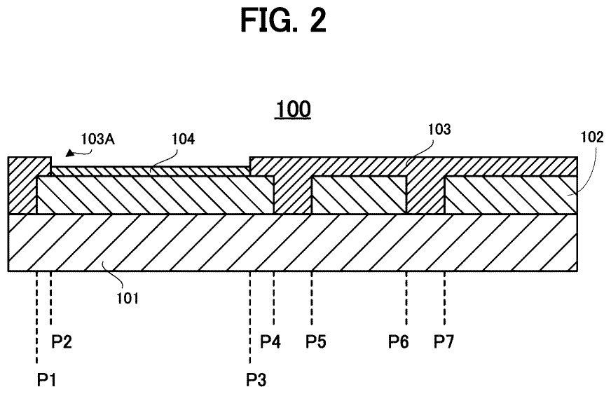

In the present embodiment, a wiring substrate 100 is described using an example of a semiconductor package substrate mounting a semiconductor element. FIG. 1 is a plan view illustrating an exemplary configuration of a main part of the wiring substrate 100 according to the present embodiment. FIG. 2 is a cross-sectional view taken along line A1-A1 illustrated in FIG. 1. Positions P1 to P7 in FIG. 1 correspond to positions P1 to P7 in FIG. 2, respectively.

The wiring substrate 100 includes a support substrate 101, a wiring layer 102, an insulating layer 103, and a protective plating layer 104. The support substrate 101 is constructed using, for example, a glass substrate, a SiN film, a SiO film, an organic film, or any other substrate materials. The wiring layer 102 is constructed using, for example, Cu or any other conductors. The insulating layer 103 is constructed using, for example, polyimide or any other insulating materials.

The wiring layer 102 is formed on the support substrate 101. The wiring layer 102 includes a wiring area 111 as a main wiring. The wiring layer 102 includes a pad 112 as an electrical contact. A metal underlayer (not illustrated) may be formed between the support substrate 101 and the wiring layer 102. The pad 112 is a SMD terminal, and have a pad region defined by an opening 103A formed in the insulating layer 103. The pad 112 may have a square shape with corner edges such as corner radii, or corner cutouts.

The wiring area 111 has a width W1 at a position near the pad 112. The width W1 is equal to or slightly less than a width W2 of the pad 112. For example, it is sufficient that the width W1 of the wiring area 111 is less than or equal to the width W2 of the pad 112. The wiring area 111 may have, in a boundary area with the pad 112, a thick wiring with a teardrop shape in which the width W1 gradually widens toward the pad 112, to prevent wire break due to stress concentration.

The insulating layer 103 covers the wiring layer 102, but includes an opening 103A for exposing at least a part of the pad 112. The protective plating layer 104 is formed on a surface of the pad 112 corresponding to the opening 103A by, for example, ENIG treatment or any other plating treatment. In FIG. 2, undercuts of the wiring layer 102 occurring in the vicinity of edges of the opening 103A and the shape of the protective plating layer 104 in this portion are omitted.

The insulating layer 103 is adhesively fixed to the support substrate 101, while adhesion to the wiring layer 102 tends to be weak. In this case, as the wiring width in the wiring layer 102 becomes wider with respect to the position at which the support substrate 101 and the insulating layer 103 are adhesively fixed, the wiring layer 102 is more likely to be peeled off from the insulating layer 103. The difference between a coefficient of thermal expansion (CTE) in a metal contained in the wiring layer 102, such as Cu, and a CTE in a material contained in the insulating layer 103, such as resin, affects peeling-off of contact surfaces of the wiring layer 102 and the insulating layer 103 when a temperature change occurs.

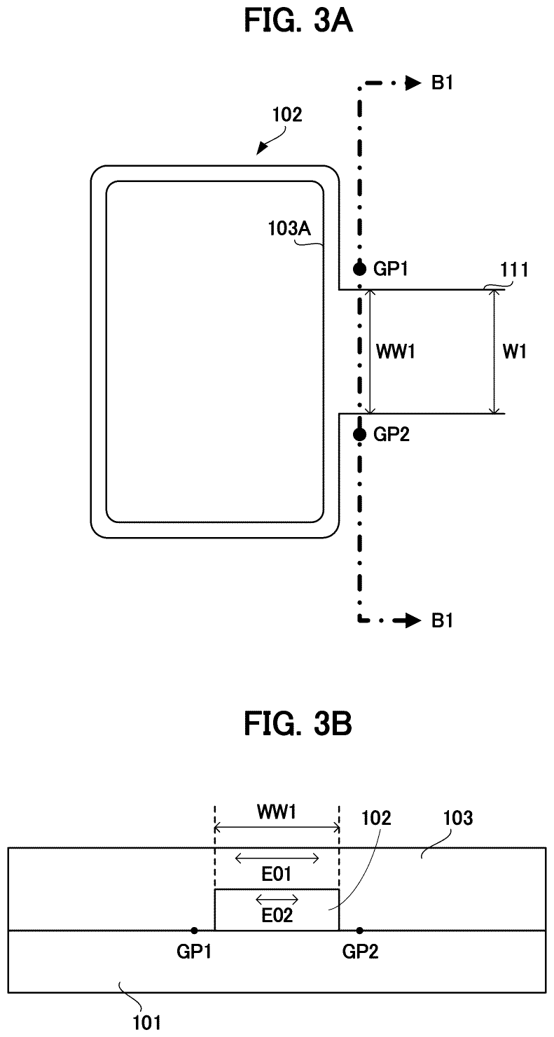

As Comparative Example 1, FIG. 3A is a plan view of the wiring layer 102 with a less wiring width WW1 as the width W1 of the wiring area 111. FIG. 3B is a cross-sectional view taken along line B1-B1 illustrated in FIG. 3A. In Comparative Example 1, the insulating layer 103 is adhesively fixed to the support substrate 101 at a position GP1 and a position GP2. The wiring layer 102 is disposed between the position GP1 and the position GP2. When the CTE of Cu constructing the wiring layer 102 is 18 ppm and the CTE of the material constructing the insulating layer 103 is 55 ppm, the amount of thermal expansion E01 of the insulating layer 103 due to temperature rise is larger than the amount of thermal expansion E02 of the wiring layer 102. However, the less wiring width WW1 results in a small distortion on the contact surfaces of the wiring layer 102 and the insulating layer 103, and the stress acting on the contact surfaces is small.

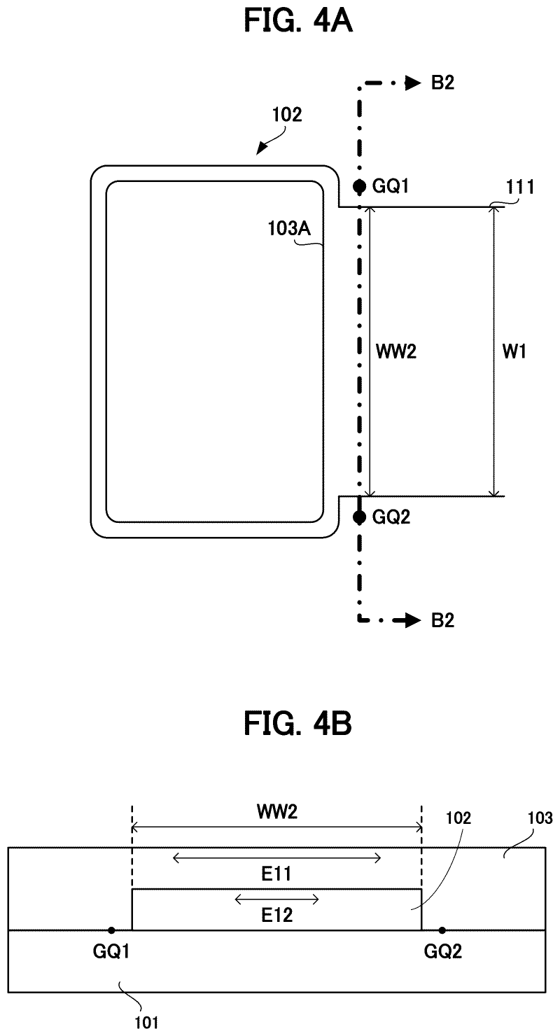

As Comparative Example 2, FIG. 4A is a plan view of the wiring layer 102 with a greater wiring width WW2 than the wiring width WW1, as the width W1 of the wiring area 111. FIG. 4B is a cross-sectional view taken along line B2-B2 illustrated in FIG. 4A. In Comparative Example 2, the insulating layer 103 is adhesively fixed to the support substrate 101 at a position GQ1 and a position GQ2. The wiring layer 102 is located between the position GQ1 and the position GQ2. When the CTEs are the same as those in Comparative Example 1, the amount of thermal expansion E11 of the insulating layer 103 due to temperature rise is significantly larger than the amount of thermal expansion E12 of the wiring layer 102. As a result, high stress acts on the contact surfaces of the wiring layer 102 and the insulating layer 103, and micro gaps due to peeling-off of the layers are likely to occur.

For example, in ENIG treatment, the treatment temperature is about 90° C. As illustrated in FIGS. 4A and 4B, a configuration in which the wiring layer 102 has the greater wiring width WW2 accelerates penetration of chemical solutions, such as an etching solution, into the micro gaps occurring on the contact surfaces of the wiring layer 102 and the insulating layer 103. In this configuration, the chemical solutions are likely to penetrate along a surface of the wiring layer 102 from the pad 112 side to the wiring area 111 side.

The wiring layer 102 of the present embodiment includes, between the wiring area 111 and the pad 112, a connection wiring area 113 as a connection area. A width W3 of the connection wiring area 113 is less than or equal to the width W2 of the pad 112. Meanwhile, the width W3 of the connection wiring area 113 is close to the width W1 of the wiring area 111 to prevent stress concentration. The connection wiring area 113 may be included in the teardrop shape of the wiring area 111. For example, the width W3 of the connection wiring area 113 may be about 140 um. The connection wiring area 113 includes a plurality of connection wiring sections 121. Each of the connection wiring sections 121 is a conductive area separated by a plurality of holes 122. Each of the holes 122 is an opening formed in the wiring layer 102, and is a non-conductive area filled with a material of the insulating layer 103. As described above, the non-conductive areas may include the plurality of holes 122. Each of the holes 122 may have a rectangular shape. The insulating layer 103 is joined to the support substrate 101 at a bottom surface of each of the holes 122. The wiring layer 102 includes the plurality of holes 122 that are formed such that the conductive area including the plurality of connection wiring sections 121 has a network structure in the connection wiring area 113. Each of the connection wiring sections 121 has a sufficiently less wiring width than the width W3 of the connection wiring area 113.

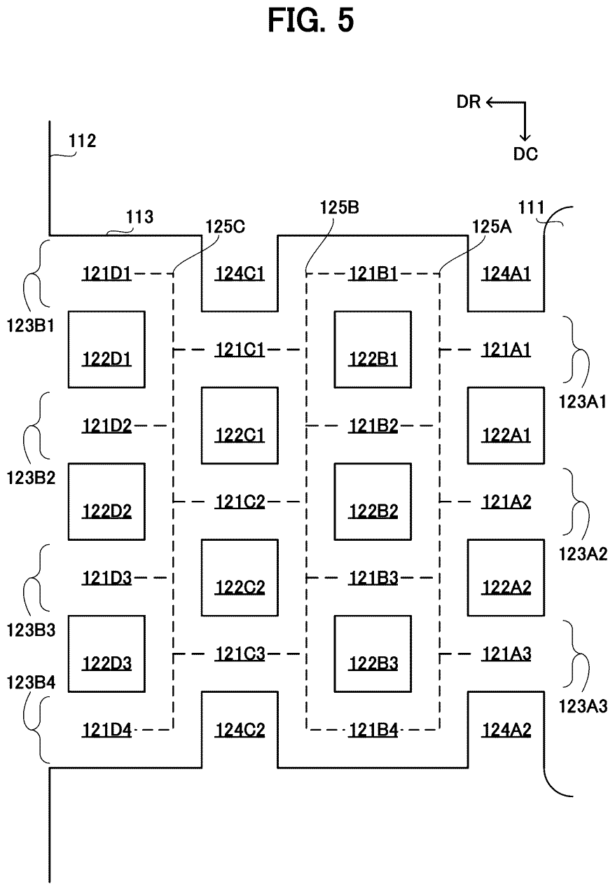

FIG. 5 is an enlarged plan view of the connection wiring area 113. The connection wiring area 113 illustrated in FIG. 5 includes a plurality of connection wiring sections 121A1 to 121A3, 121B1 to 121B4, 121C1 to 121C3, and 121D1 to 121D4. The connection wiring section 121A1 and the connection wiring section 121A2 are separated by a hole 122A1. The connection wiring section 121A2 and the connection wiring section 121A3 are separated by a hole 122A2. The connection wiring section 121B1 and the connection wiring section 121B2 are separated by a hole 122B1. The connection wiring section 121B2 and the connection wiring section 121B3 are separated by a hole 122B2. The connection wiring section 121B3 and the connection wiring section 121B4 are separated by a hole 122B3. The connection wiring section 121C1 and the connection wiring section 121C2 are separated by a hole 122C1. The connection wiring section 121C2 and the connection wiring section 121C3 are separated by a hole 122C2. The connection wiring section 121D1 and the connection wiring section 121D2 are separated by a hole 122D1. The connection wiring section 121D2 and the connection wiring section 121D3 are separated by a hole 122D2. The connection wiring section 121D3 and the connection wiring section 121D4 are separated by a hole 122D3.

The connection wiring section 121A1 is formed between the hole 122A1 and an edge notch 124A1 from which the wiring layer 102 is removed. The connection wiring section 121A3 is formed between the hole 122A2 and an edge notch 124A2 from which the wiring layer 102 is removed. The connection wiring section 121C1 is formed between the hole 122C1 and an edge notch 124C1 from which the wiring layer 102 is removed. The connection wiring section 121C3 is formed between the hole 122C2 and an edge notch 124C2 from which the wiring layer 102 is removed. Each of the edge notches 124A1, 124A2, 124C1, and 124C2 is a notch formed at an edge of the wiring layer 102, and is a non-conductive area filled with the material of the insulating layer 103. As described above, the non-conductive areas may include a plurality of edge notches 124, such as the edge notches 124A1, 124A2, 124C1, and 124C2. The insulating layer 103 is joined to the support substrate 101 at a bottom surface of each of the edge notches 124A1, 124A2, 124C1, and 124C2.

The connection wiring area 113 includes, as a plurality of first connection areas, a plurality of connection areas 123A1 to 123A3 that are located on the wiring area 111 side. One end of the connection wiring section 121A1 is connected to the wiring area 111 in the connection area 123A1. One end of the connection wiring section 121A2 is connected to the wiring area 111 in the connection area 123A2. One end of the connection wiring section 121A3 is connected to the wiring area 111 in the connection area 123A3. As described above, the one end of each of the connection wiring sections 121A1 to 121A3 is directly connected to the wiring area 111.

The other end of each of the connection wiring sections 121A1 to 121A3 is connected to one end of each of the connection wiring sections 121B1 to 121B4 via a bending route illustrated by a dashed line 125A. The other end of each of the connection wiring sections 121B1 to 121B4 is connected to one end of each of the connection wiring sections 121C1 to 121C3 via a bending route illustrated by a dashed line 125B. The other end of each of the connection wiring sections 121C1 to 121C3 is connected to one end of each of the connection wiring sections 121D1 to 121D4 via a bending route illustrated by a dashed line 125C.

The other end of each of the connection wiring sections 121D1 to 121D4 is directly connected to the pad 112. The connection wiring area 113 includes, as a plurality of second connection areas, a plurality of connection areas 123B1 to 123B4 that are located on the pad 112 side. The other end of the connection wiring section 121D1 is connected to the pad 112 in the connection area 123B1. The other end of the connection wiring section 121D2 is connected to the pad 112 in the connection area 123B2. The other end of the connection wiring section 121D3 is connected to the pad 112 in the connection area 123B3. The other end of the connection wiring section 121D4 is connected to the pad 112 in the connection area 123B4.

The holes 122A1 and 122A2 are arranged alternately with the holes 122B1 to 122B3 across the bending route illustrated by the dashed line 125A. The holes 122B1 to 122B3 are arranged alternately with the holes 122C1 and 122C2 across the bending route illustrated by the dashed line 125B. The holes 122C1 and 122C2 are arranged alternately with the holes 122D1 to 122D3 across the bending route illustrated by the dashed line 125C. Thus, in the connection wiring area 113, the plurality of holes 122 as the non-conductive areas corresponding to voids in the network structure are individually separated by the plurality of connection wiring sections 121 included in the conductive area with the network structure, and are arranged alternately with each other.

The plurality of connection wiring sections 121A1 to 121A3 are arranged such that midpoints or intermediate points thereof, are aligned on an identical line along a vertical direction or a column direction DC as a first direction in FIG. 5. The plurality of connection wiring sections 121B1 to 121B4 are arranged such that midpoints or intermediate points thereof are aligned on an identical line along the vertical direction or the column direction DC as the first direction in FIG. 5. The plurality of connection wiring sections 121C1 to 121C3 are arranged such that midpoints or intermediate points thereof are aligned on an identical line along the vertical direction or the column direction DC as the first direction in FIG. 5. The plurality of connection wiring sections 121D1 to 121D4 are arranged such that midpoints or intermediate points thereof are aligned on an identical line along the vertical direction or the column direction DC as the first direction in FIG. 5.

Thus, among the connection wiring sections 121A1 to 121A3, one connection wiring section and another adjacent connection wiring section are formed such that the midpoints or intermediate points thereof are located on an identical line in the first direction. Among the connection wiring sections 121B1 to 121B4, one connection wiring section and another adjacent connection wiring section are formed such that the midpoints or intermediate points thereof are located on an identical line in the first direction. Among the connection wiring sections 121C1 to 121C3, one connection wiring section and another adjacent connection wiring section are formed such that the midpoints or intermediate points thereof are located on an identical line in the first direction. Among the connection wiring sections 121D1 to 121D4, one connection wiring section and another adjacent connection wiring section are formed such that the midpoints or intermediate points thereof are located on an identical line in the first direction.

The plurality of connection wiring sections 121A1 to 121A3 are arranged so as to have centerlines or intermediate lines along a horizontal direction or a row direction DR as a second direction in FIG. 5 that are different lines parallel to centerlines or intermediate lines of the plurality of connection wiring sections 121B1 to 121B4, which are adjacent to the connection wiring sections 121A1 to 121A3 via the bending route illustrated by the dashed line 125A. For example, the centerline or intermediate lines of the connection wiring section 121A1 is parallel to the centerlines or intermediate lines of the connection wiring sections 121B1 and 121B2, and is equidistant from these two centerlines or intermediate lines. The plurality of connection wiring sections 121B1 to 121B4 are arranged so as to have centerlines or intermediate lines along the horizontal direction or the row direction DR as the second direction in FIG. 5 that are different lines parallel to centerlines or intermediate lines of the plurality of connection wiring sections 121C1 to 121C3, which are adjacent to the connection wiring sections 121B1 to 121B4 via the bending route illustrated by the dashed line 125B. The plurality of connection wiring sections 121C1 to 121C3 are arranged so as to have centerlines or intermediate lines along the horizontal direction or the row direction DR as the second direction in FIG. 5 that are different lines parallel to centerlines or intermediate lines of the plurality of connection wiring sections 121D1 to 121D4, which are adjacent to the connection wiring sections 121C1 to 121C3 via the bending route illustrated by the dashed line 125C. Thus, in the wiring layer 102 of the connection wiring area 113, the plurality of adjacent connection wiring sections 121 along the first direction are aligned on the same lime, while the plurality of adjacent connection wiring sections 121 along the second direction are arranged alternatively with each other. The plurality of connection wiring sections 121 are included in the conductive area with the network structure.

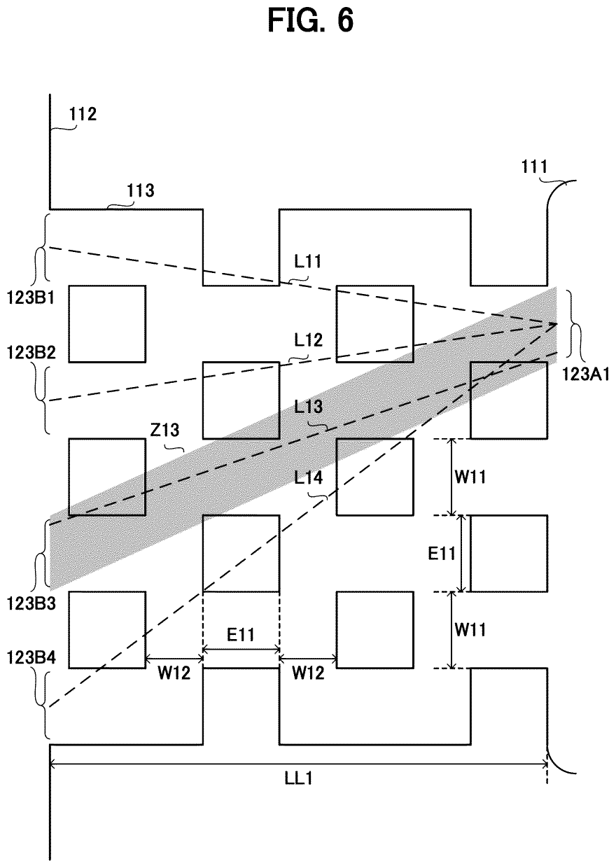

FIG. 6 is an enlarged plan view of the connection wiring area 113 from another point of view. FIG. 6 illustrates line segments L11 to L14 that each connect one point in the connection area 123A1 included in the plurality of first connection areas and one point in each of the connection areas 123B1 to 123B4 included in the plurality of second connection areas. The line segment L11 includes one end point included in the connection area 123A1 and the other end point included in the connection area 123B1. The line segment L12 includes one end point included in the connection area 123A1 and the other end point included in the connection area 123B2. The line segment L13 includes one end point included in the connection area 123A1 and the other end point included in the connection area 123B3. The line segment L14 includes one end point included in the connection area 123A1 and the other end point included in the connection area 123B4.

The line segment L11 passes through the connection wiring sections 121A1 and 121D1 as the conductive areas between the one point in the connection area 123A1 and the one point in the connection area 123B1. The line segment L11 also passes through the hole 122B1 and the edge notch 124C1 as the non-conductive areas. Thus, the connection wiring sections 121A1 and 121D1 as the conductive areas and the hole 122B1 and the edge notch 124C1 as the non-conductive areas are located on the line segment L11 between the one point in the connection area 123A1 and the one point in the connection area 123B1.

The line segment L12 passes through the connection wiring sections 121A1 and 121D2 as the conductive areas between the one point in the connection area 123A1 and the one point in the connection area 123B2. The line segment L12 also passes through the holes 122B1 and 122C1 as the non-conductive areas. Thus, the connection wiring sections 121A1 and 121D2 as the conductive areas and the holes 122B1 and 122C1 as the non-conductive areas are located on the line segment L12 that connects the one point in the connection area 123A1 and the one point in the connection area 123B2.

The line segment L13 passes through the connection wiring sections 121A1, 121B2, 121C2, and 121D3 as the conductive areas between the one point in the connection area 123A1 and the one point in the connection area 123B3. The line segment L13 also passes through the holes 122A1 and 122D2 as the non-conductive areas. Thus, the connection wiring sections 121A1, 121B2, 121C2, and 121D3 as the conductive areas and the holes 122A1 and 122D2 as the non-conductive areas are located on the line segment L13 that connects the one point in the connection area 123A1 and the one point in the connection area 123B3.

The line segment L14 passes through the connection wiring sections 121A1 and 121D4 as the conductive areas between the one point in the connection area 123A1 and the one point in the connection area 123B4. The line segment L14 also passes through the holes 122A1, 122B2, 122C2, and 122D3 as the non-conductive areas. Thus, the connection wiring sections 121A1 and 121D4 as the conductive areas and the holes 122A1, 122B2, 122C2, and 122D3 as the non-conductive areas are located on the line segment L14 that connects the one point in the connection area 123A1 and the one point in the connection area 123B4.

Similarly, at least one conductive area and at least one non-conductive area are located on each of a plurality of line segments connecting one point in the connection area 123A2 included in the plurality of first connection areas and one point in each of the connection areas 123B1 to 123B4 included in the plurality of second connection areas. Similarly, at least one conductive area and at least one non-conductive area are located on each of a plurality of line segments connecting one point in the connection area 123A3 included in the plurality of first connection areas and one point in each of the connection areas 123B1 to 123B4 included in the plurality of second connection areas. As described above, in the connection wiring area 113, at least one conductive area and at least one non-conductive area may be located on a line segment connecting one point in each of the first connection areas and one point in each of the second connection areas.

The plurality of holes 122 in the connection wiring area 113 are formed such that the conductive area including the plurality of connection wiring sections 121 constructs a network structure. Each of the connection wiring sections 121 preferably has a width W11 less than or equal to 30 μm, such as 20 μm. Each of the holes 122 has, for example, a square shape. Each of the holes 122 preferably has a length E11 of each side greater than or equal to 10 μm, such as 20 μm. However, an aspect ratio that is a ratio of the thickness of the insulating layer 103 to the length E11 is preferably less than or equal to 1. For example, when the insulating layer 103 has a thickness of 10 μm, each of the holes 122 may be formed to have a length E11 greater than or equal to 10 μm. Each of the bending routes illustrated by the dashed lines 125A to 125C preferably has a width W12 less than or equal to 30 μm, such as 15 μm. Each of the bending routes may have a less width than the connection wiring sections 121, or may have the same width as the connection wiring sections 121. The connection wiring area 113 preferably has a length LL1 between the wiring area 111 and the pad 112 greater than or equal to 100 um to prevent progression of peeling-off toward the wiring area 111. The distance between the positions P3 and P4 illustrated in FIGS. 1 and 2 is preferably the same as the width W12.

Since the plurality of connection wiring sections 121 have the width W11, each of the connection areas 123A1 to 123A3 and 123B1 to 123B4 have a predetermined width. The predetermined width corresponds to a distance between one point on the upper end side, which is referred to as an upper end point, and one point on the lower end side, which is referred to as a lower end point, in wavy brackets illustrated in FIG. 6. The plurality of connection areas 123A1 to 123A3 are located on the wiring area 111 side, and the plurality of connection areas 123B1 to 123B4 are located on the pad 112 side. In accordance with positions of end points, a configuration may be provided in which at least some of a plurality of line segments connecting one point in each of the plurality of connection area 123A1 to 123A3 and one point in each of the plurality of connection area 123B1 to 123B4 do not pass through the non-conductive areas. For example, between the connection areas 123A1 and 123B3 illustrated in FIG. 6, a line segment other than the line segment L13 can be defined that passes through the connection wiring sections 121A1, 121B2, 121C2, and 121D3 and does not passes any non-conductive areas. In this case, at least one conductive area and at least one non-conductive area may be located in a linear band Z13 that is illustrated in gray and extends between the connection areas 123A1 and 123B3. The linear band Z13 illustrated in FIG. 6 corresponds to the connection areas 123A1 and 123B3, and is formed between a straight line connecting the upper end points and a straight line connecting the lower end points. In addition, a straight line between the upper end point and the lower end point of the connection area 123A1 and a straight line between the upper end point and the lower end point of the connection area 123B3 form two sides at both ends of the linear band Z13. As described above, a plurality of linear bands can be defined between the plurality of connection areas 123A1 to 123A3 and the plurality of connection areas 123B1 to 123B4. The plurality of connection areas 123A1 to 123A3, as the plurality of first connection areas, are located on the wiring area 111 side. The plurality of connection areas 123B1 to 123B4, as the plurality of second connection area, are located on the pad 112 side. Each of the linear bands is a band-shaped area corresponding to one of the connection areas 123A1 to 123A3 and one of the connection areas 123B1 to 123B4 and formed between a line segment connecting upper end points and a line segment connecting lower end points. Each of the linear bands has, as two sides at both ends, a line segment between an upper end point and a lower end point of one of the connection areas 123A1 to 123A3 and a line segment between an upper end point and a lower end point of one of the connection areas 123B1 to 123B4.

The plurality of linear bands connecting the plurality of connection areas 123A1 to 123A3 and the plurality of connection areas 123B1 to 123B4 may include one or more linear bands in which no non-conductive areas are located. At least one conductive area and at least one non-conductive area may be located in, among the plurality of linear bands, a linear band with the shortest distance between the wiring area 111 and the pad 112 or two or more linear bands with a relatively short distance between the wiring area 111 and the pad 112. The plurality of connection areas 123A1 to 123A3 are the plurality of first connection areas located on the wiring area 111 side. The plurality of connection areas 123B1 to 123B4 are the plurality of second connection areas located on the pad 112 side. Thus, at least one conductive area and at least one non-conductive area may be allowed to be located in all or some of the plurality of linear bands connecting the plurality of connection areas 123A1 to 123A3 as the plurality of first connection areas and the plurality of connection areas 123B1 to 123B4 as the plurality of second connection areas. In this case, the non-conductive area that can be located in the linear bands may be all of at least one continuous non-conductive area or a part of at least one continuous non-conductive area. For example, a configuration may be provided in which a part of at least one continuous non-conductive area, such as a hole 122A1, is located in a linear band, and the other part of this continuous non-conductive area is located in the wiring area 111 or the pad 112 as well as a part of the connection wiring area 113 not included in the linear band, or only in the part of the connection wiring area 113 not included in the linear band.

In the connection wiring area 113, the non-conductive areas including the plurality of holes 122 can be located on line segments each connecting one point in each of the connection areas 123A1 to 123A3 on the wiring area 111 side and one point in each of the connection areas 123B1 to 123B4 on the pad 112 side. The plurality of connection wiring sections 121 allow the wiring area 111 and the pad 112 to be connected with each other via the bending routes illustrated by the dashed lines 125A to 125C. This extends or narrows routes of penetration of chemical solutions, such as an etching solution, in the connection wiring area 113, and allows the wiring layer 102 to resist penetration of the chemical solutions.

In the connection wiring area 113, the plurality of connection wiring sections 121 included in the conductive area have a sufficiently less width W11 than the width W3 of the connection wiring area 113. The plurality of holes 122 are filled with the material of the insulating layer 103. The support substrate 101 and the insulating layer 103 are joined to each other at the bottom surface of each of the plurality of holes 122. This prevents peeling-off of the insulating layer 103 from the wiring layer 102 in the connection wiring area 113, and allows the wiring layer 102 to resist penetration of chemical solutions.

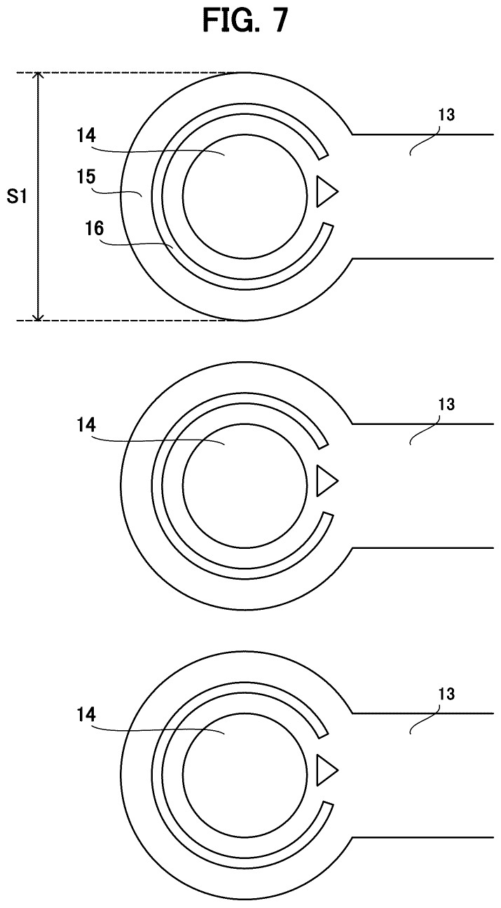

FIG. 7 illustrates the shape and the like of a land 14 disclosed in Japanese Patent Application Publication No. 2011-34988. The land 14 is formed at an edge of a wiring area 13 illustrated in FIG. 7. An outer peripheral area 15 is formed away from the land 14 and surrounds the land 14. A plurality of insulating layers are joined at a gap 16 between the land 14 and the outer peripheral area 15. In such a structure in which the outer peripheral area 15 is located around the land 14, the overall size S1 thereof is larger. When a plurality of lands 14 are located corresponding to a plurality of wiring areas 13 on a substrate, increase in the overall size S1 makes high-density arrangement difficult and leads to reduction in the degree of integration.

In contrast, in the wiring layer 102 of the present embodiment, while the connection wiring area 113 is located between the wiring area 111 and the pad 112, there is no need to provide a structure corresponding to the outer peripheral area 15 around the pad 112. Since the width W3 of the connection wiring area 113 is less than the width W2 of the pad 112, the connection wiring area 113 does not affect the degree of integration of the pad 112. Thus, the wiring layer 102 including the connection wiring area 113 can allow high-density arrangement of the pad 112 and improve the degree of integration thereof.

### Embodiment 2

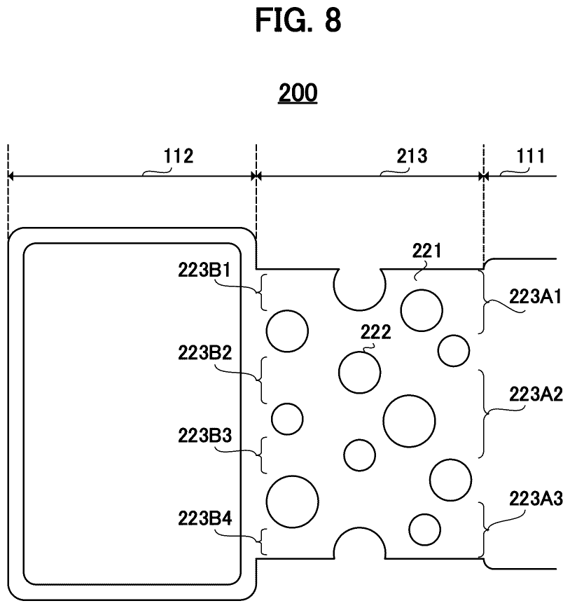

A wiring substrate 200 according to Embodiment 2 is described with reference to FIG. 8. In the following description, components common to those of Embodiment 1 are denoted with the same reference signs.

In the wiring substrate 200, the wiring layer 102 includes, between the wiring area 111 and the pad 112, a connection wiring area 213 as a connection area. The connection wiring area 213 includes a plurality of connection wiring sections 221. Each of the connection wiring sections 221 is a conductive area separated by a plurality of holes 222. Each of the holes 222 is an opening formed in the wiring layer 102, and is a non-conductive area filled with the material of the insulating layer 103. Each of the holes 222 may have a different shape from that of the holes 122 of Embodiment 1, such as a circular shape. It is sufficient that the connection wiring area 213 has the same width W3 as the connection wiring area 113 of Embodiment 1.

The connection wiring area 213 includes, as the plurality of first connection areas, a plurality of connection areas 223A1 to 223A3 that are located on the wiring area 111 side. The connection wiring area 213 also includes, as the plurality of second connection areas, a plurality of connection areas 223B1 to 223B4 that are located on the pad 112 side. In this case, at least one conductive area and at least one non-conductive area may be located on any line segment connecting one point in each of the connection areas 223A1 to 223A3 included in the plurality of first connection areas and one point in each of the connection areas 223B1 to 223B4 included in the plurality of second connection areas. As described above, in the connection wiring area 213, at least one conductive area and at least one non-conductive area can be located on a line segment connecting one point in each of the first connection areas and one point in each of the second connection areas. The connection areas 223A1 to 223A3 and 223B1 to 223B4 have a predetermined width. In accordance with positions of end points, a configuration may be provided in which a plurality of line segments each connecting one point in each of the plurality of connection area 223A1 to 223A3 and one point in each of the plurality of connection area 223B1 to 223B4 do not pass through the non-conductive areas. In this case, at least one conductive area and at least one non-conductive area may be located in a linear band connecting one of the plurality of connection areas 223A1 to 223A3 and one of the plurality of connection areas 223B1 to 223B4. Alternatively, the plurality of linear bands connecting the plurality of connection areas 223A1 to 223A3 as the plurality of first connection areas located on the wiring area 111 side and the plurality of connection areas 223B1 to 223B4 as the plurality of second connection areas located on the pad 112 side may include one or more linear bands in which no non-conductive areas are located. However, at least one conductive area and at least one non-conductive area may be located in, among the plurality of linear bands connecting the plurality of connection areas 223A1 to 223A3 and the plurality of connection areas 223B1 to 223B4, at least a linear band with the shortest distance between the wiring area 111 and the pad 112, or two or more linear bands with a relatively short distance between the wiring area 111 and the pad 112. Thus, at least one conductive area and at least one non-conductive area may be allowed to be located in all or some of the plurality of linear bands connecting the plurality of connection areas 223A1 to 223A3 included in the plurality of first connection areas and the plurality of connection areas 223B1 to 223B4 included in the plurality of second connection areas. In this case, all of at least one continuous non-conductive area may be located in a linear band. A configuration may be provided in which a part of at least one continuous non-conductive area is located in a linear band, and the other part of this continuous non-conductive area is located in the wiring area 111 or the pad 112 as well as a part of the connection wiring area 213 not included in the linear band, or only in the part of the connection wiring area 213 not included in the linear band.

The plurality of holes 222 may have mutually different sizes. The plurality of holes 222 that separate the plurality of connection wiring sections 221 are preferably formed such that the width W11 of at least some of the connection wiring sections 221 is less than or equal to 30 μm. In the connection wiring area 213, the plurality of holes 222 may be randomly arranged so as to extend or narrow routes of penetration of chemical solutions, such as an etching solution, from the pad 112 side to the wiring area 111 side in the conductive area including the plurality of connection wiring sections 221. This allows the wiring layer 102 to resist penetration of the chemical solutions.

It is sufficient that, in the connection wiring area 213, the plurality of connection wiring sections 221 included in the conductive area have a sufficiently less width W11 than the width W3 of the connection wiring area 213. The plurality of holes 222 are filled with the material of the insulating layer 103. The support substrate 101 and the insulating layer 103 are joined to each other at a bottom surface of each of the holes 222. This prevents peeling-off of the insulating layer 103 from the wiring layer 102 in the connection wiring area 213, and allows the wiring layer 102 to resist penetration of chemical solutions.

### Embodiment 3

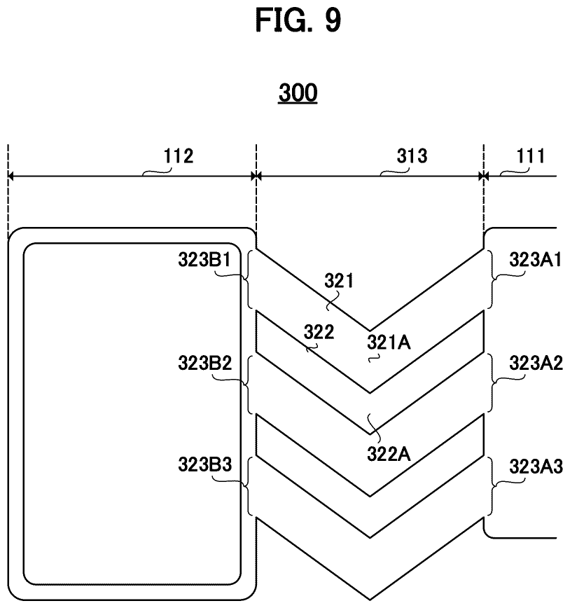

A wiring substrate 300 according to Embodiment 3 is described with reference to FIG. 9. In the following description, components common to those of Embodiment 1 are denoted with the same reference signs.

In the wiring substrate 300, the wiring layer 102 includes, between the wiring area 111 and the pad 112, a connection wiring area 313 as a connection area. The connection wiring area 313 includes a plurality of connection wiring sections 321. Each of the connection wiring sections 321 has a bending 321A, and is a conductive area separated by a plurality of holes 322. Each of the holes 322 is an opening formed in the wiring layer 102, and is a non-conductive area filled with the material of the insulating layer 103. Each of the holes 322 has a different shape from that of the holes 122 of Embodiment 1, such as a slit shape including a bending 322A. It is sufficient that the connection wiring area 313 has the same width W3 as the connection wiring area 113 of Embodiment 1.

The connection wiring area 313 includes, as the plurality of first connection areas, a plurality of connection areas 323A1 to 323A3 that are located on the wiring area 111 side. The connection wiring area 313 also includes, as the plurality of second connection areas, a plurality of connection areas 323B1 to 323B4 that are located on the pad 112 side. In this case, at least one conductive area and at least one non-conductive area may be located on any line segment connecting one point in each of the connection areas 323A1 to 323A3 included in the plurality of first connection areas and one point in each of the connection areas 323B1 to 323B4 included in the plurality of second connection areas. As described above, in the connection wiring area 313, at least one conductive area and at least one non-conductive area can be located on a line segment connecting one point in each of the first connection areas and one point in each of the second connection areas. In accordance with positions of end points, a configuration may be provided in which a plurality of line segments each connecting one point in each of the plurality of connection area 323A1 to 323A3 and one point in each of the plurality of connection area 323B1 to 323B4 do not pass through the non-conductive areas. In this case, at least one conductive area and at least one non-conductive area may be located in a linear band connecting one of the plurality of connection areas 323A1 to 323A3 and one of the plurality of connection areas 323B1 to 323B4. When each of the connection wiring section 321 includes the bending 321A, at least one conductive area and at least one non-conductive area may be located in any of the plurality of linear bands connecting the plurality of connection areas 323A1 to 323A3 as the plurality of first connection areas located on the wiring area 111 side and the plurality of connection areas 323B1 to 323B4 as the plurality of second connection areas located on the pad 112 side. Thus, at least one conductive area and at least one non-conductive area may be allowed to be arranged on all of the plurality of linear bands connecting the connection areas 323A1 to 323A3 included in the plurality of first connection areas and the connection areas 323B1 to 323B4 included in the plurality of second connection areas. In this case, a configuration may be provided in which a part of at least one continuous non-conductive area is located in a linear band, and the other part of this continuous non-conductive area may be located in the wiring area 111 or the pad 112 as well as a part of the connection wiring area 313 not included in the linear band, or only in the part of the connection wiring area 313 not included in the linear band.

The plurality of holes 322 that separate the plurality of connection wiring sections 321 are preferably formed such that each of the connection wiring sections 321 has a width W11 less than or equal to 30 μm. In the connection wiring area 313, each of the holes 322 is formed to have the bending 322A so as to extend or narrow routes of penetration of chemical solutions, such as an etching solution, from the pad 112 side to the wiring area 111 side in the conductive areas including the plurality of connection wiring sections 321. This allows the wiring layer 102 to resist penetration of the chemical solutions.

It is sufficient that, in the connection wiring area 313, the plurality of connection wiring sections 321 included in the conductive area have a sufficiently less width W11 than the width W3 of the connection wiring area 313. The plurality of holes 322 are filled with the material of the insulating layer 103. The support substrate 101 and the insulating layer 103 are joined to each other at the bottom surface of each of the holes 222. This prevents peeling-off of the insulating layer 103 from the wiring layer 102 in the connection wiring area 313, and allows the wiring layer 102 to resist penetration of the chemical solutions.

### Embodiment 4

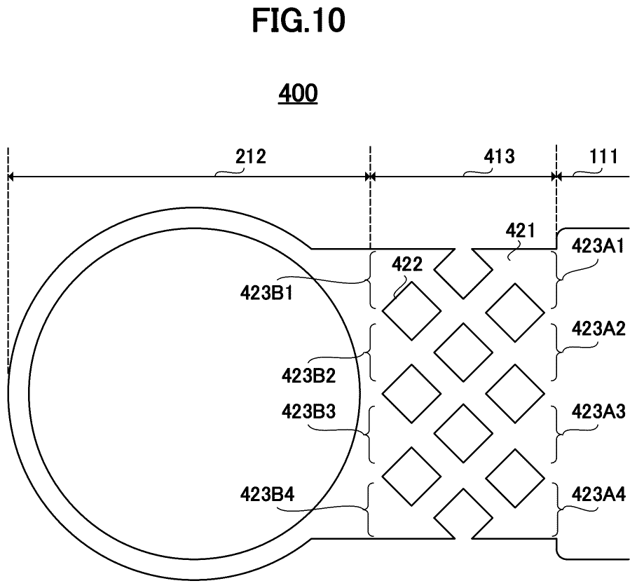

A wiring substrate 400 according to Embodiment 4 is described with reference to FIG. 10. In the following description, components common to those of Embodiment 1 are denoted with the same reference signs.

In the wiring substrate 400, the wiring layer 102 includes a pad 212 as an electrical contact. The pad 212 is the same solder mask defined (SMD) terminal as the pad 112. The pad 212 may have a circular shape, unlike the pad 112. The wiring layer 102 includes, between the wiring area 111 and the pad 212, a connection wiring area 413 as a connection area. The connection wiring area 413 includes a plurality of connection wiring sections 421. Each of the connection wiring sections 421 is a conductive area separated by a plurality of holes 422. Each of the holes 422 is an opening formed in the wiring layer 102, and is a non-conductive area filled with the material of the insulating layer 103. Each of the holes 422 has a different shape from that of the holes 122 of Embodiment 1, such as a diamond shape. It is sufficient that the connection wiring area 413 has the same width W3 as the connection wiring area 113 of Embodiment 1. The plurality of holes 422 are formed in the wiring layer 102 such that the conductive area including the plurality of connection wiring sections 421 has, in the connection wiring area 413, a mesh structure that is similar to the network structure of Embodiment 1.

The connection wiring area 413 includes, as the plurality of first connection areas, a plurality of connection areas 423A1 to 423A4 that are located on the wiring area 111 side. The connection wiring area 413 also includes, as the plurality of second connection areas, a plurality of connection areas 423B1 to 423B4 that are located on the pad 212 side. In this case, at least one conductive area and at least one non-conductive area may be located on any line segment connecting one point in each of the connection areas 423A1 to 423A4 included in the plurality of first connection areas and one point in each of the connection areas 423B1 to 423B4 included in the plurality of second connection areas. As described above, in the connection wiring area 413, at least one conductive area and at least one non-conductive area can be located on a line segment connecting one point in each of the first connection areas and one point in each of the second connection areas. The connection areas 423A1 to 423A4 and 423B1 to 423B4 have a predetermined width. In accordance with positions of end points, a configuration may be provided in which a plurality of line segments each connecting one point in each of the plurality of connection area 423A1 to 423A4 and one point in each of the plurality of connection area 423B1 to 423B4 do not pass through the non-conductive areas. In this case, at least one conductive area and at least one non-conductive area may be located in a linear band connecting one of the plurality of connection areas 423A1 to 423A4 and one of the plurality of connection areas 423B1 to 423B4. Alternatively, the plurality of linear bands connecting the plurality of connection areas 423A1 to 423A4 as the plurality of first connection areas located on the wiring area 111 side and the plurality of connection areas 423B1 to 423B4 as the plurality of second connection areas located on the pad 212 side may include one or more linear bands in which no non-conductive areas are located. However, at least one conductive area and at least one non-conductive area may be located in, among the plurality of linear bands connecting the plurality of connection areas 423A1 to 423A4 and the plurality of connection areas 423B1 to 423B4, a linear band with the shortest distance between the wiring area 111 and the pad 212 or two or more linear bands with a relatively short distance between the wiring area 111 and the pad 212. Thus, at least one conductive area and at least one non-conductive area may be allowed to be located in all or some of the plurality of linear bands connecting the plurality of connection areas 423A1 to 423A4 included in the plurality of first connection areas and the plurality of connection areas 423B1 to 423B4 included in the plurality of second connection areas. In this case, all of at least one continuous non-conductive area may be located in a linear band. A configuration may be provided in which a part of at least one continuous non-conductive area is located in a linear band, and the other part of this continuous non-conductive area may be located in the wiring area 111 or the pad 212 as well as a part of the connection wiring area 413 not included in the linear band, or only in the part of the connection wiring area 413 not included in the linear band.

The plurality of holes 422 that separate the plurality of connection wiring areas 421 are preferably formed such that each of the connection wiring sections 421 has a width W11 less than or equal to 30 um. The wiring layer 102 includes, in the connection wiring area 413, the plurality of holes 422 as non-conductive areas corresponding to voids of a mesh structure and arranged alternatively with each other, in contrast to a plurality of connection wiring sections 421 as conductive areas of the mesh structure. This extends or narrows routes of penetration of chemical solutions, such as an etching solution, from the pad 212 side to the wiring area 111 side in the conductive area including the plurality of connection wiring sections 421. Such a configuration allows the wiring layer 102 to resist penetration of the chemical solutions.

It is sufficient that, in the connection wiring area 413, the plurality of connection wiring sections 421 included in the conductive area have a sufficiently less width W11 than the width W3 of the connection wiring area 413. The plurality of holes 422 are filled with the material of the insulating layer 103. The support substrate 101 and the insulating layer 103 are joined to each other at a bottom surface of each of the holes 422. This prevents peeling-off of the insulating layer 103 from the wiring layer 102 in the connection wiring area 413, and allows the wiring layer 102 to resist penetration of chemical solutions.

The wiring layer 102 may include, between the wiring area 111 and the pad 212, the same connection wiring area 113 as that of Embodiment 1, instead of the connection wiring area 413 illustrated in FIG. 10. Alternatively, the wiring layer 102 may include, between the wiring area 111 and the circular-shaped pad 212, the same connection wiring area 213 as that of Embodiment 2 or a connection wiring area with any structure similar to that of the connection wiring area 213, instead of the connection wiring area 413 illustrated in FIG. 10.

### Embodiment 5

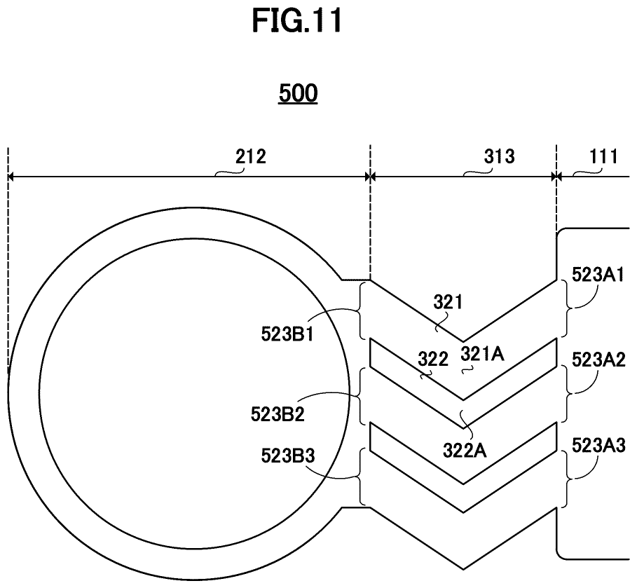

A wiring substrate 500 according to Embodiment 5 is described with reference to FIG. 11. In the following description, components common to those of Embodiment 1 are denoted with the same reference signs.

In the wiring substrate 500, the wiring layer 102 includes the same pad 212 as that of Embodiment 4. The wiring layer 102 includes, between the wiring area 111 and the pad 212, the same connection wiring area 313 as that of Embodiment 3.

In Embodiment 5, the connection wiring area 313 includes, as the plurality of first connection areas, a plurality of connection areas 523A1 to 523A3 that are located on the wiring area 111 side. In Embodiment 5, the connection wiring area 313 also includes, as the plurality of second connection areas, a plurality of connection areas 523B1 to 523B3 that are located on the pad 212 side. In this case, at least one conductive area and at least one non-conductive area may be located on any line segment connecting one point in each of the connection areas 523A1 to 523A3 included in the plurality of first connection areas and one point in each of the connection areas 523B1 to 523B3 included in the plurality of second connection areas. As described above, in the connection wiring area 313, at least one conductive area and at least one non-conductive area can be located on a line segment connecting one point in each of the first connection areas and one point in each of the second connection areas. In addition, at least one conductive area and at least one non-conductive area may be allowed to be located in all of the plurality of linear bands connecting the plurality of connection areas 523A1 to 523A3 included in the plurality of first connection areas and the plurality of connection areas 523B1 to 523B3 included in the plurality of second connection areas. In this case, a configuration may be provided in which a part of at least one continuous non-conductive area is located in a linear band, and the other part of this continuous non-conductive area is located in the wiring area 111 or the pad 212 as well as a part of the connection wiring area 313 not included in the linear band, or only in the part of the connection wiring area 313 not included in the linear band. Such a configuration allows the wiring layer 102 to resist penetration of the chemical solutions as well as Embodiment 3.

### Embodiment 6

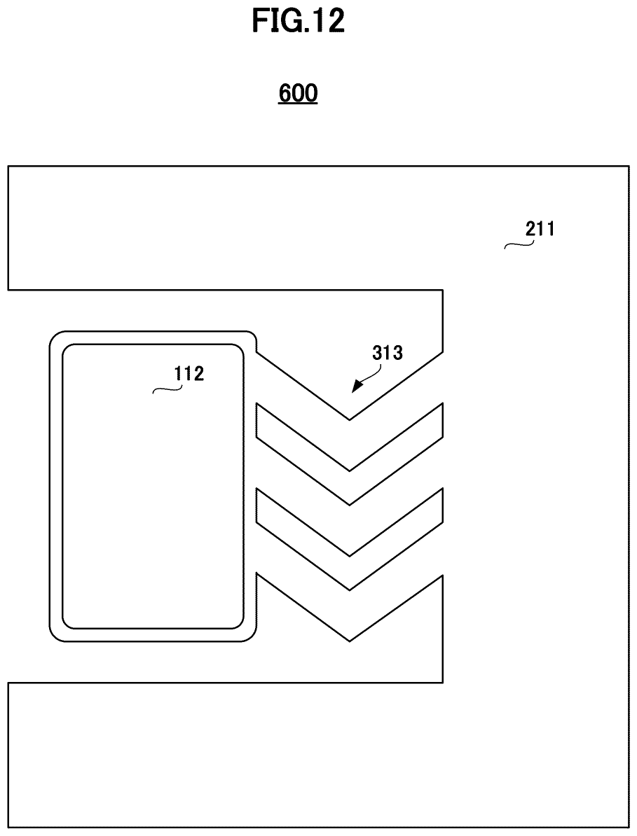

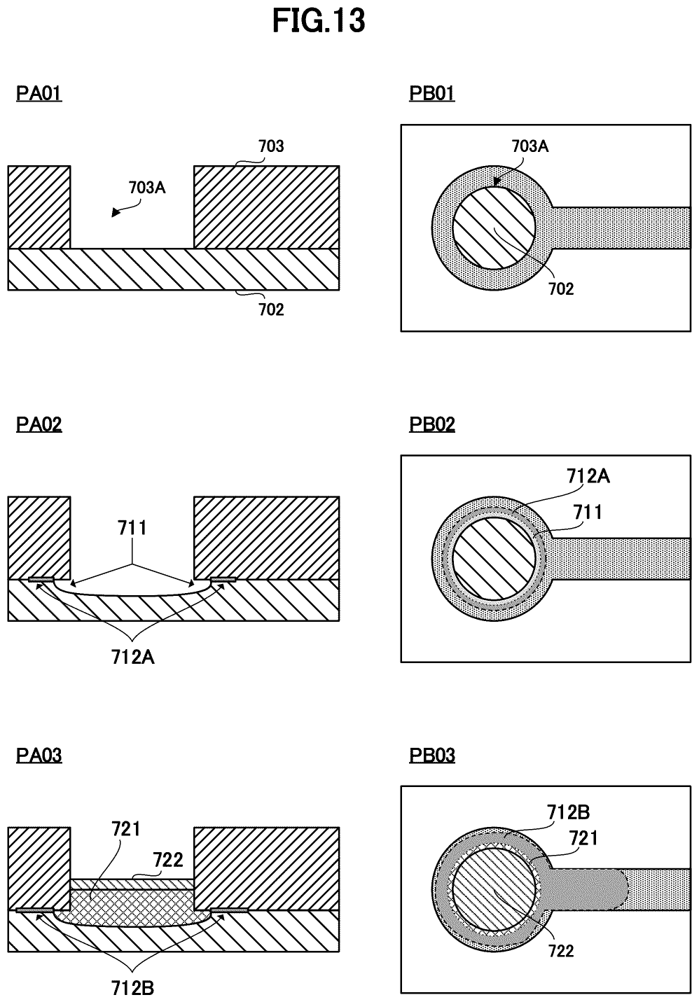

A wiring substrate 600 according to Embodiment 6 is described with reference to FIG. 12. In the following description, components common to those of the other embodiments are denoted with the same reference signs.

In the wiring substrate 600, the wiring layer 102 includes a planar conductive area 211 such as a ground electrode, instead of the wiring area 111. In FIG. 12, the wiring layer 102 includes, between the planar conductive area 211 and the pad 112, the same connection wiring area 313 as that of Embodiment 3. The wiring layer 102 may include the same pad 212 as that of Embodiment 4, instead of the pad 112. The wiring layer 102 may include the same connection wiring area 113 as that of Embodiment 1, instead of the connection wiring area 313. The wiring layer 102 may include the same connection wiring area 213 as that of Embodiment 2, instead of the connection wiring area 313. Such configurations allow the wiring layer 102 to resist penetration of the chemical solutions as well as the other embodiments.

### Modified Examples

Embodiments have been described, but various modifications can be made to the present disclosure without departing from the spirit and scope of the present disclosure.

In Embodiment 1 that corresponds to FIG. 1 or Embodiment 4 that corresponds to FIG. 10, the conductive area with the network structure or the mesh structure may be replaced by a conductive area with a honeycomb structure. In Embodiment 3 that corresponds to FIG. 9, Embodiment 5 that corresponds to FIG. 11, or Embodiment 6 that corresponds to FIG. 12, the conductive areas with the bending in the connection wiring area may be replaced by conductive areas with a zigzag structure or a meander structure. In addition, it is sufficient that the wiring layer 102 includes a plurality of holes such that the conductive area including the plurality of connection wiring section has any structure extending or narrowing routes of penetration of chemical solutions in the connection wiring area.

In the wiring substrate 100 illustrated in FIG. 1, the wiring substrate 200 illustrated in FIG. 8, and the wiring substrate 400 illustrated in FIG. 10, the connection wiring area 113 is drawn from the pad 112 along the horizontal direction or the row direction DR as the second direction, and is connected to the wiring area 111. On the other side, when the wiring area 111 is not located in the second direction or the first direction with respect to a position at which the pad 112 is located, the connection wiring area 113 may be drawn from the pad 112 in a diagonal direction. In a structure in which the connection wiring area 113 is drawn from the rectangular-shaped pad 112 in the diagonal direction, the connection wiring area 113 may be drawn from a corner of the pad 112.

The wiring layer 102 is not limited to that formed on the support substrate 101. For example, the wiring layer 102 on a multilayer wiring substrate may be formed between a first insulating layer and a second insulating layer that are not included in the support substrate 101. It is sufficient that the first insulating layer is an interlayer insulating layer in a multilayer structure. It is sufficient that the second insulating layer is a protective insulating layer covering the wiring layer 102. Alternatively, both the first insulating layer and the second insulating layer may be interlayer insulating layers, and it is sufficient that the first insulating layer and the second insulating layer have adhesion exceeding that between the insulating layer 103 and the wiring layer 102.

Without departing from the spirit and scope of the present disclosure, any size, which includes length, width, thickness, and all or some of the above, shape, structure, architecture, arrangement, combination, and other technical features of the conductive areas in the wiring layer 102 may be determined based on any constraints including wiring strength, electrical resistance, insulation spacing, circuit layout, integration density, wiring processing technology, and all or some of the above. Without departing from the spirit and scope of the present invention, any total number of rows, columns, and the like, size, which includes both or either of length and width, shape, and other technical features of the plurality of holes and the other non-conductive areas may be determined. The technical features of the wiring layer 102 is applicable to other techniques by abstracting such features as a configuration of a wiring member.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

1. A wiring substrate comprising:
a support substrate;
a wiring layer formed on the support substrate and including main wiring and an electrical contact;
an insulating layer having an opening corresponding to at least a part of the electrical contact, the insulating layer covering the wiring layer; and
a protective plating layer formed on a surface of the electrical contact at the opening, wherein
the wiring layer includes a connection area between the main wiring and the electrical contact,
the connection area includes
a plurality of first connection areas located on a side of the main wiring, and
a plurality of second connection areas located on a side of the electrical contact, and
at least one conductive area and at least one non-conductive area are allowed to be located in a linear band connecting one of the plurality of first connection areas and one of the plurality of second connection areas.

2. The wiring substrate according to claim 1, wherein
a plurality of the non-conductive areas are formed such that the conductive area has a network structure in the connection wiring area.

3. The wiring substrate according to claim 2, wherein
in the connection area, the plurality of non-conductive area are formed alternatively with each other corresponding to voids of the network structure.

4. The wiring substrate according to claim 1, wherein
the connection area includes a plurality of connection wiring sections arranged on an identical line along a first direction and arranged alternatively with each other along a second direction.

5. The wiring substrate according to claim 1, wherein
the connection area includes a plurality of the non-conductive areas having a rectangular shape.

6. The wiring substrate according to claim 1, wherein
the connection area includes a plurality of the non-conductive areas having a circular shape.

7. The wiring substrate according to claim 1, wherein
the connection area includes a plurality of the non-conductive areas having a slit shape including a bending.

8. The wiring substrate according to claim 1, wherein
the connection area includes a plurality of connection wiring sections, and
each of the plurality of connection wiring sections has a width less than or equal to 30 μm.

9. The wiring substrate according to claim 1, wherein
the connection area has a length greater than or equal to 100 μm between the main wiring and the electrical contact.

10. A wiring member comprising:
main wiring;
an electrical contact; and
a connection area provided between the main wiring and the electrical contact, wherein
the connection area includes
a plurality of first connection areas located on a side of the main wiring, and
a plurality of second connection areas located on a side of the electrical contact, and
at least one conductive area and at least one non-conductive area are allowed to be located in a linear band connecting one of the plurality of first connection areas and one of the plurality of second connection areas.
